(19) United States
(12) Patent Application Publication
(10) Pub. No.: US 2009/0159002 A1
(43) Pub. Date: Jun. 25, 2009

(54) Gas distribution plate with annular plenum having a sloped ceiling for uniform distribution

(76) Inventors: Kallol Bera, (US); Shahid Rauf, (US)

Correspondence Address: LAW OFFICE OF ROBERT M. WALLACE, 2112 EASTMAN AVENUE, SUITE 102, VENTURA, CA, 93003, US

(21) Appl. No.: 12/004,448

(22) Filed: Dec. 19, 2007

(51) Int. Cl. C23C 16/44; B05B 1/18

(52) U.S. Cl. 118/715; 239/548

(57) ABSTRACT

A gas distribution plate for a plasma reactor has an annular gas distribution plenum with an array of gas injection holes and a gas injection port at one end of the annular plenum, the plenum being progressively constricted in cross-sectional area along its azimuthal path by a sloping ceiling.

### TECHNICAL FIELD

The disclosure concerns a gas distribution plate for introducing process gases into the chamber of a plasma reactor. In particular, it concerns a gas distribution plate from which gas is dispersed from an annular hollow plenum supplied by a gas injection port.

### BACKGROUND

In semiconductor circuit fabrication, the progress toward smaller devices sizes on the order of nanometers requires greater reduction in particle contamination. Such particle contamination can occur during plasma processing of the semiconductor wafer. One of the sources of particle contamination in plasma processing is the gas distribution plate. Typically, the gas distribution plate is a metal piece such as aluminum, and gas is injected into the plasma reactor chamber through small gas injection orifices in the metal gas distribution plate. Under certain conditions, plasma generated in the chamber can enter some of the orifices and arc within those orifices, which draws metal particles from the gas distribution plate into the plasma. Such metal particles can deposit on the wafer, creating device defects and reducing product yield. Thus, there is a need for an improved configuration of a gas distribution plate to minimize particle deposition in the chamber and/or the wafer.

### SUMMARY

In accordance to an embodiment of the present invention, a plasma reactor gas distribution plate is provided for injecting process gas into the interior of a plasma reactor chamber with uniform gas distribution. The gas distribution plate comprises a disk-shaped plate and a first hollow annular plenum supported by the disk-shaped plate. The annular plenum is concentric with an axis of symmetry of the disk-shaped plate, the plenum comprising an annular plenum floor and an annular plenum ceiling facing the annular plenum floor. Plural gas injection holes are provided in the plenum floor and a gas injection port is coupled to the plenum at a supply end of the plenum. The annular plenum ceiling height is maximum at the supply end of the plenum. The plenum ceiling slopes toward the floor along an azimuthal path of the plenum whereby the height decreases along the azimuthal path. In one embodiment, the plenum ceiling slopes sufficiently so that the height decreases by a factor of two or more over 360 degrees of travel along the azimuthal path. In another embodiment, the plenum ceiling slopes sufficiently so that the height decreases by a factor of two or more over 180 degrees of travel along the azimuthal path.

### BRIEF DESCRIPTION OF THE DRAWINGS

So that the manner in which the above recited embodiments of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a side view of a gas distribution plate in accordance with an embodiment.

FIG. 2 is a bottom view corresponding to FIG. 1.

FIG. 3 depicts a plasma reactor having a gas distribution plate in accordance with another embodiment.

FIG. 4 illustrates the gas distribution plate of the plasma reactor of FIG. 3.

FIG. 5 is a bottom view corresponding to FIG. 4.

FIGS. 6A, 6B, 6C, 6D and 6E are cross-sectional views taken along lines A-A, B-B, C-C, D-D and E-E, respectively, of FIG. 5.

FIG. 7 is a side view of a plasma reactor having a gas distribution plate in accordance with a further embodiment.

FIG. 8 illustrates the gas distribution plate of the plasma reactor of FIG. 7.

FIG. 9 illustrates a gas distribution plate in accordance with another embodiment.

FIG. 9A is a cut-away view of a portion of the gas distribution plate of FIG. 9.

FIG. 10 illustrates a gas distribution plate in accordance with a variation of the embodiment of FIG. 9.

FIG. 11 illustrates a gas distribution plate in accordance with another variation of the embodiment of FIG. 9.

FIG. 12 illustrates a gas distribution plate in accordance with a variation of the embodiment of FIG. 10.

FIG. 13 depicts a plasma reactor having a gas distribution plate in accordance with a further embodiment.

FIG. 14 illustrates the gas distribution plate of FIG. 13.

FIG. 15 depicts a gas distribution plate in accordance with a further embodiment.

To facilitate understanding, identical reference numerals have been used, where possible, to designate identical elements that are common to the figures. The drawings in the figures are all schematic and not to scale.

### DETAILED DESCRIPTION

We have discovered that arcing tends to occur during transitions from one process gas to another process gas. In particular, transitioning from a more conductive process gas to a less conductive process gas can cause arcing, particularly if the gas distribution plate is of a type having a relatively long internal gas flow path. As the process gas transition progresses, the process gas in one portion of the gas distribution plate differs from that in another portion of the gas distribution plate. This is because replacement of the old process gas (e.g., a higher conductivity species) by the new process gas (e.g., a lower conductivity species) takes a finite amount of time. During this transition, the higher conductivity process gas tends to absorb more of the applied RF source power. As the higher conductivity gas volume decreases during the transition to the new (lower conductivity) process gas, the absorbed power density in the higher conductivity process gas increases until arcing occurs. The problem is due in part to the thinner plasma sheath thickness of the plasma formed with the higher conductivity process gas, which enables that portion of the plasma to enter into the gas injection orifices in the gas distribution plate. Once inside those orifices, the higher power absorption and hollow cathode effects can create arcing. Depending upon the gas distribution path length within the gas distribution plate, the complete replacement of one process gas with another can take several seconds, during which contamination induced defects on the wafer can increase.

To avoid such problems, what is needed is a way of reducing the gas replacement transition time down to a few hundred milliseconds to reduce or possibly prevent arcing.

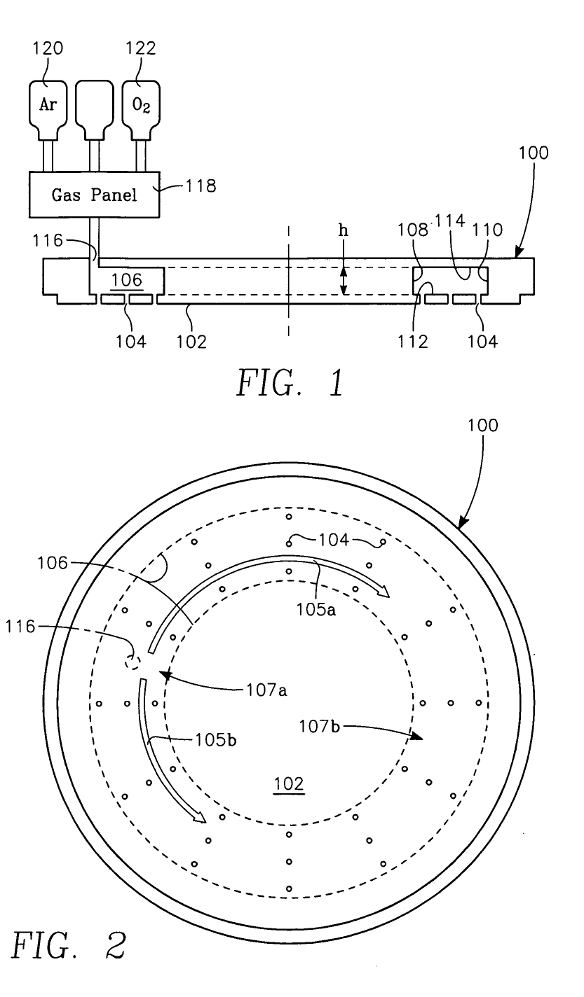

Referring to FIGS. 1 and 2, a gas distribution plate 100 may constitute or be a part of the ceiling of the vacuum chamber of a plasma reactor (not shown in FIGS. 1 and 2). The bottom surface 102 of the gas distribution plate has gas injection orifices 104 arranged (for example) in an annular array, as illustrated in FIG. 2. The depiction of the orifices 104 is not to scale, and in general the orifices are much smaller than shown in the drawing (e.g., on the order of one or a few millimeters in diameter). The orifices 104 each can be circular, round, or the like, in shape. Process gas is supplied to the annular array of orifices 104 through an annular internal plenum 106 formed within the gas distribution plate 100. The annular plenum 106 may extend around 360 degrees through the gas distribution plate 100 in the embodiment of FIGS. 1 and 2. The annular plenum 106 is enclosed by an inner side wall 108, an outer side wall 110, a floor 112 and a ceiling 114. The gas injection orifices 104 extend through the plenum floor 112 to the bottom surface 102 of the gas distribution plate 100. A gas supply inlet 116 extends through the top of the gas distribution plate 100 and through the plenum ceiling 114. The gas supply inlet 116 is coupled to a gas control panel 118. Plural process gas supplies furnish process gas to the gas control panel 118, such as (for example) an argon gas supply 120 and an oxygen gas supply 122. The gas flow path through the annular plenum 106 is along respective clockwise and counterclockwise azimuthal (e.g., circumferential) paths 105a, 105b. Each path 105a, 105b extends 180 degrees from a supply zone 107a at the supply inlet 116 to a terminal zone end 107b. The supply and terminal zones 107a, 107b are 180 degrees apart. During a transition from argon process gas to oxygen process gas, arcing may occur in the orifices 104 nearest the terminal zone 107b of the plenum 106.

During a transition from a more conductive or electropositive process gas such as argon to an electronegative gas such as oxygen, distribution of the different gas species throughout the plenum 106 is non-uniform, with oxygen predominating at the supply zone 107a near the inlet 116 and argon predominating in the terminal zone 107b or the region farthest away from the inlet 116. The argon plasma in the remote region has a higher ion density and smaller sheath thickness comparable to the diameter of the orifices 104, so that the plasma enters the orifices 104 in the terminal zone 107b to cause arcing and, consequently, particle contamination in the plasma. The localized argon plasma around the terminal zone 107b has lower plasma impedance, greater ion density and greater RF power deposition, all of which increases the tendency for arcing during the transition time.

In order to reduce the gas transition time in the gas distribution plate 100 of FIGS. 1 and 2, the plenum ceiling height, h (FIG. 1), may be reduced to reduce the volume of the plenum 106. The plenum ceiling height, h, is the distance between the plenum ceiling 114 and the plenum floor 112. The gas transition time is the time required to completely replace a first process gas (e.g., argon) with a second process gas (e.g., oxygen) in the plenum 106. A reduction in the ceiling height h (e.g., by a factor of two) would reduce the gas transition time, thereby reducing the defects induced during transition. However, such a reduction in the ceiling height h can reduce gas conductance in the plenum. Such a reduction in gas conductance may cause the azimuthal distribution of gas pressure and velocity around the plenum 106 to be non-uniform. The resulting gas injection may be azimuthally non-uniform. Specifically, the gas flow rate through the orifices 104 may decrease along the length of the azimuthal gas flow path through the plenum 106. This non-uniformity may give rise to process non-uniformity (e.g., a non-uniform etch rate distribution) across the surface of the wafer or workpiece being processed.

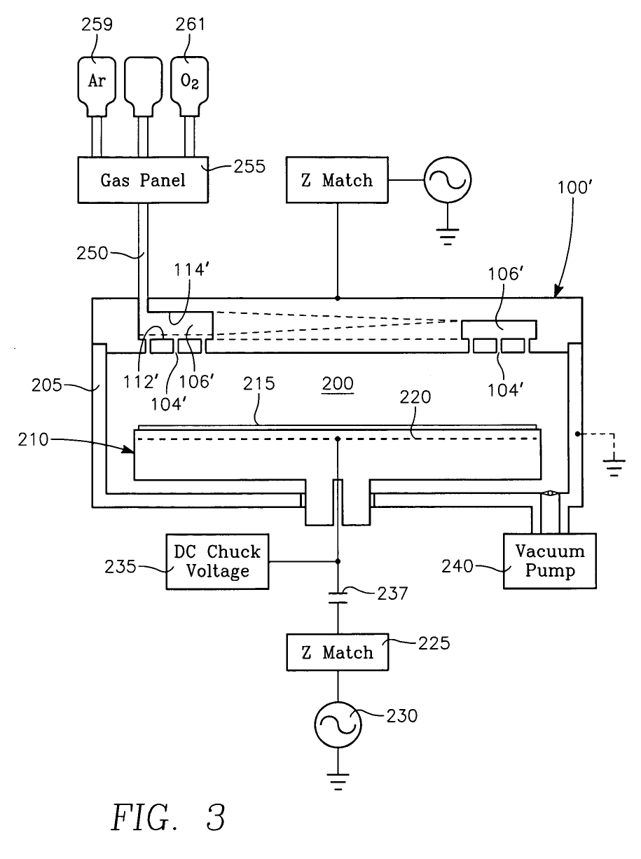

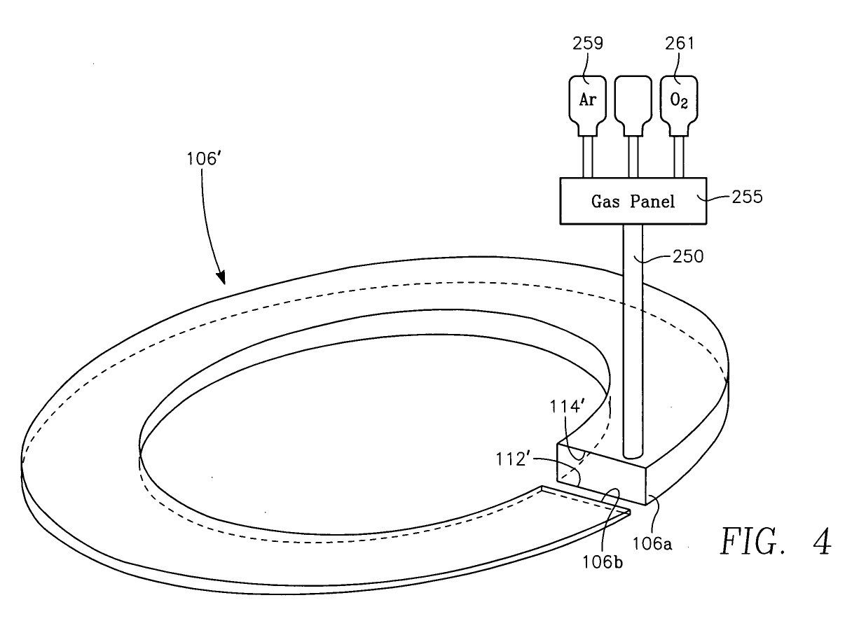

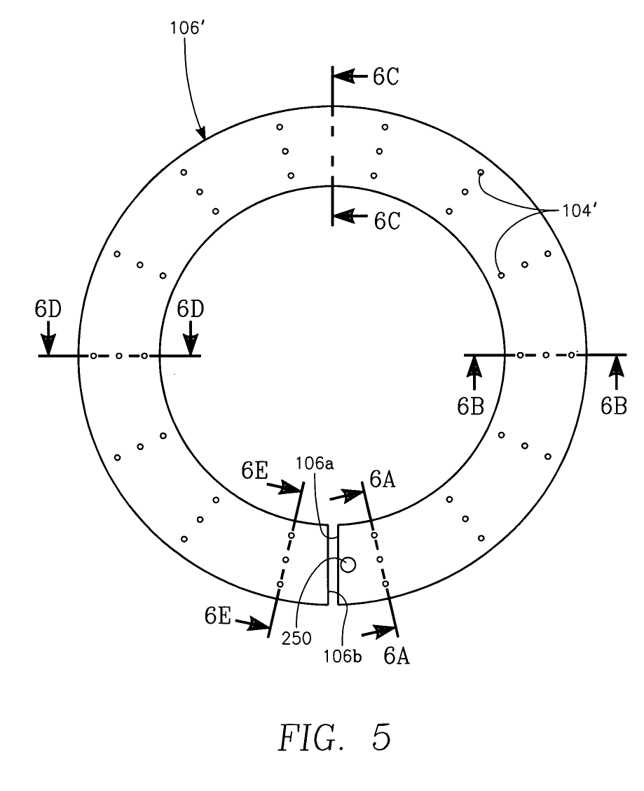

FIG. 3 is a side view of a reactor including a gas distribution plate in accordance with one embodiment; FIG. 4 is a perspective view of a plenum in the gas distribution plate of the embodiment of FIG. 3; and FIG. 5 is a plan view of a bottom surface of the gas distribution plate of FIG. 3. The reactor of FIG. 3 has a vacuum chamber 200 enclosed by a gas distribution plate 100′ (that forms a ceiling) and a side wall 205. A support 210 can hold a workpiece or wafer 215 during plasma processing. The support 210 can include an internal insulated electrode 220 that may be coupled through an RF impedance match 225 to an RF plasma bias power generator 230. If the support 210 is an electrostatic chuck (ESC), then a D.C. chuck voltage supply 235 may be coupled to the electrode 220. A blocking capacitor 237 isolates the RF impedance match 225 from the D.C. supply 235, in one embodiment. Chamber pressure is controlled by a vacuum pump 240. The gas distribution plate 100′ has an internal annular plenum 106′. The plenum 106′ has a ceiling 114′ and a floor 112′ with gas injection orifices 104′ extending through the floor 112′. A gas supply inlet 250 extends through the top of the gas distribution plate 100′ and through the plenum ceiling 114′. The gas supply inlet 250 is coupled to a gas control panel 255. Plural process gas supplies furnish process gas to the gas control panel 255, such as (for example) an argon gas supply 259 and an oxygen gas supply 261. The gas flow path through the annular plenum 106′ is in the azimuthal direction and extends around 360 degrees beginning at a supply end 106a of the plenum 106′ at the supply inlet 250 to a terminal end 106b of the plenum 106′.

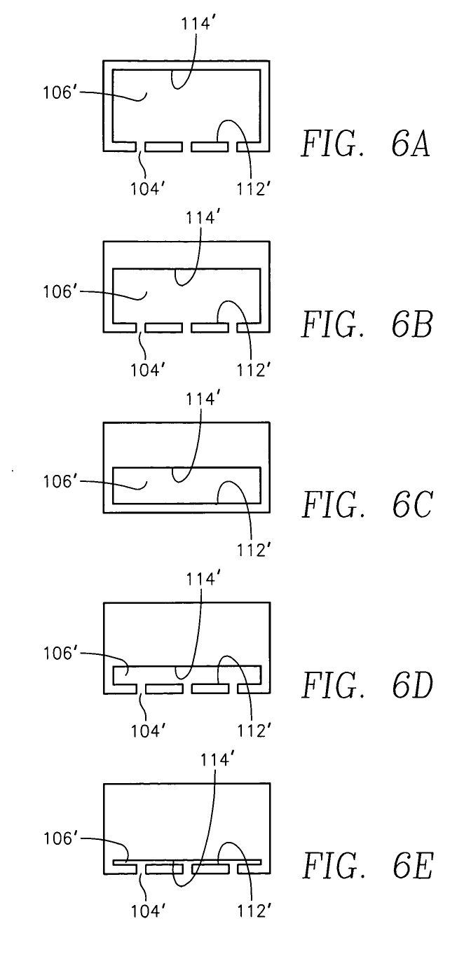

The embodiment of FIGS. 3, 4 and 5 includes a feature in which the cross-sectional area of the plenum 106′ is continuously reduced along the azimuthal direction of the gas flow path through the plenum 106′. In one embodiment of this feature, the plenum ceiling 114′ continuously slopes downwardly along the azimuthal gas flow path of the plenum 106′, as illustrated in FIGS. 3 and 4. Specifically, the ceiling height is maximum at the plenum supply end 106a and is minimum at the plenum terminal end 106b. This is best depicted in the series of cross-sectional views of FIGS. 6A, 6B, 6C, 6D and 6E, which show the decreasing cross-section of the plenum 106′ in successive locations along the azimuthal path of the plenum 106′. This constriction in the cross-sectional area of the plenum 106′ can counter the tendency of gas flow rate through the orifices 104′ to decrease along the length of the azimuthal flow path through the plenum 106′. This feature can improve process uniformity across the surface of the workpiece or wafer. In one example, the slope of the ceiling 114′ was sufficient so that the ceiling height decreased by factor of two over 360 degrees of travel (a complete circuit) along the azimuthal path of the plenum 106′.

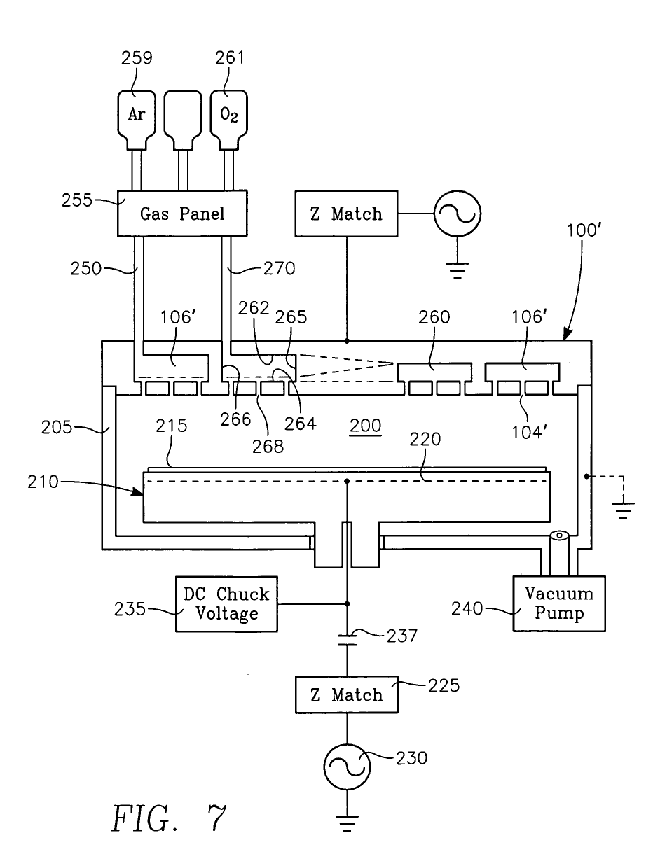

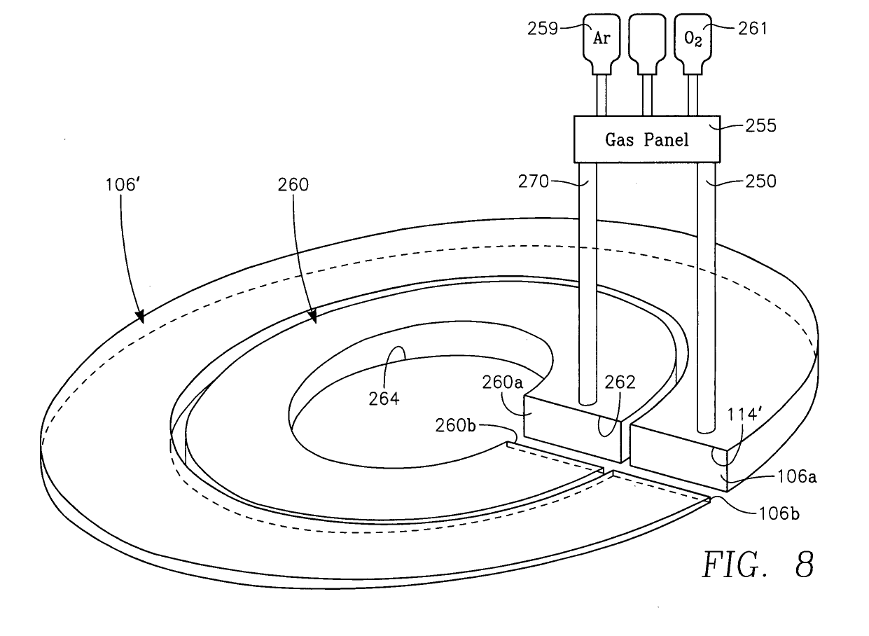

FIGS. 7 and 8 depict a variation of the embodiment of FIGS. 3-5, in which a second annular plenum 260 is provided in the gas distribution plate 100′ concentric with and surrounded by the annular plenum 106′. The first plenum 106′ is an outer plenum while the second plenum 260 is an inner plenum. The inner plenum 260 is enclosed by a ceiling 262, a floor 264 and sidewalls 265, 266. Gas injection orifices 268 extend through the floor 264, and a single gas inlet 270 through the plenum ceiling 262 is coupled to the gas control panel 255 (or to another gas control panel not shown). The gas control panel 255 may control gas flow to the outer and inner plenums 106′ and 260 independently. The gas flow path of the inner plenum 260 extends from a supply end 260a near the inlet 270 to a terminal end 260b of the inner plenum 260. The ceiling 262 of the inner plenum 260 slopes downwardly from the supply end 260a to the terminal end 260b.

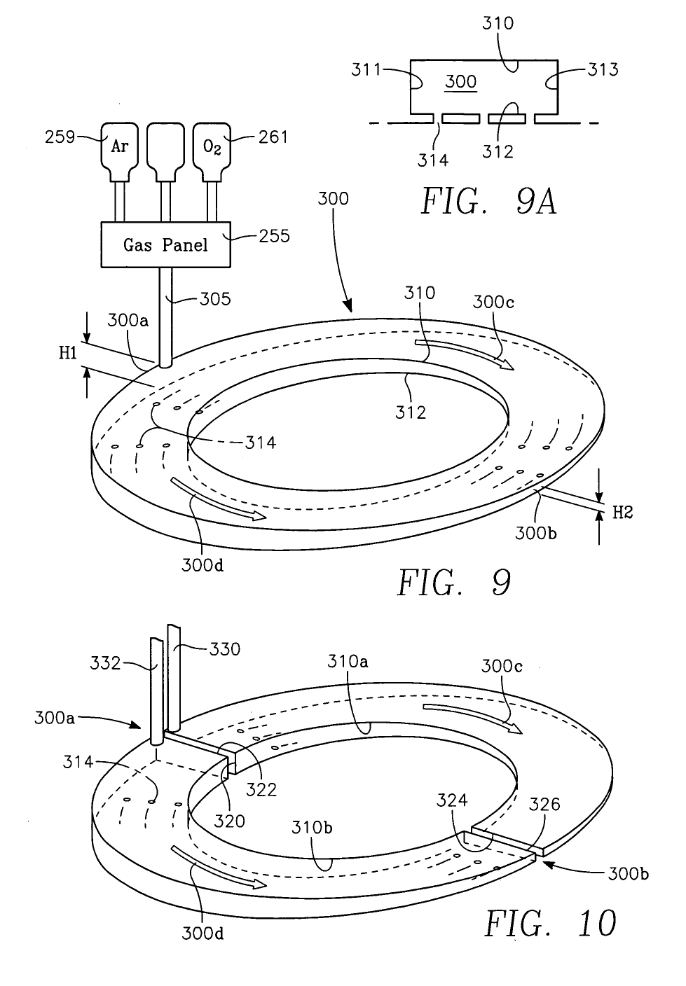

FIG. 9 depicts a variation of the embodiment of FIG. 4, in which the plenum 106′ is replaced by a plenum 300 whose supply end 300a and terminal end 300b are separated by 180 degrees, there being a pair of opposing half-circular gas flow paths 300c, 300d in the circular plenum 300. In the embodiment of FIG. 9, the plenum 300 forms a complete circle. As shown in FIG. 9A, the plenum 300 is enclosed by a ceiling 310, side walls 311, 313 and a floor 312 with orifices 314 extending through the floor 312. Gas from a gas supply inlet 305 flows from a supply zone 300a of the plenum 300 to a terminal zone 300b of the plenum 300 along the opposing arcuate paths 300c, 300d of the plenum 300. Gas flow in the arcuate path 300c follows a clockwise 180 degree turn, while gas flow in the arcuate path 300d follows a counterclockwise 180 degree turn. The ceiling 310 slopes downwardly starting at the supply portion 300a (at which the ceiling height H1 is greatest) and ending at the opposite portion 300b (at which the ceiling height H2 is the smallest). The floor 312 is similar to the floor 112′ of FIG. 5. In one example, the slope of the ceiling 310 of FIG. 9 was sufficient so that the ceiling height above the floor 312 decreased by a factor of two over 180 degrees of travel (a half-circuit) along the azimuthal path of the plenum 300.

FIG. 10 depicts a variation of the embodiment of FIG. 9 in which the two half-circular paths 300c, 300d of the plenum 300 are physically separated by respective supply end walls 320, 322 at the supply end 300a and terminal end walls 324, 326 at the opposite end 300b. In this embodiment, the two plenum paths 300c, 300d form respective complementary 180 degree half plenums, with respective sloping ceilings 310a, 310b. Gas is supplied to the respective half-circular plenum paths 300c, 300d through respective gas inlets 330, 332.

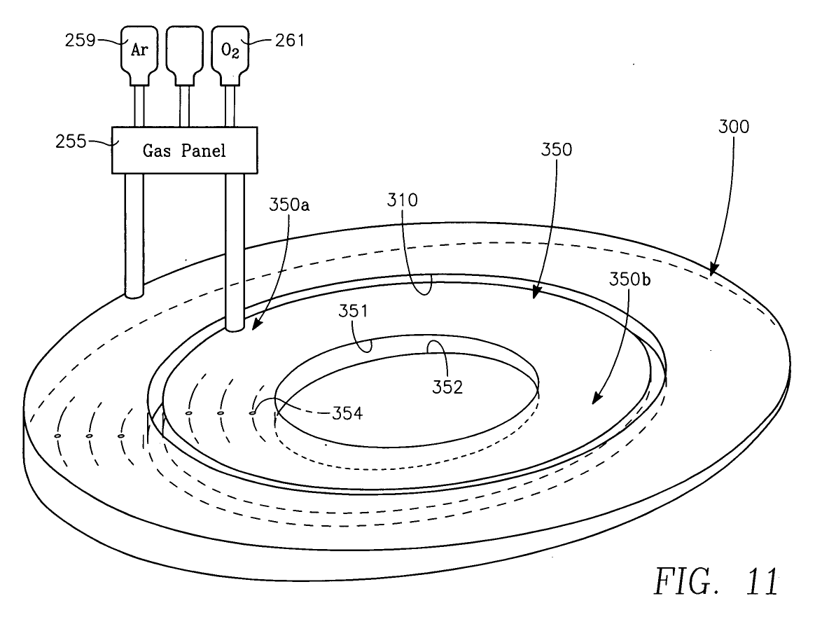

FIG. 11 depicts a variation of the embodiment of FIG. 9, in which a smaller annular plenum 350 is surrounded by the plenum 300, so that the plenums 300, 350 correspond to outer and inner gas distribution zones. The inner plenum 350 is similar in structure to the outer plenum 300, having a ceiling 351a floor 352 with gas injection orifices 354 in the floor 352. The inner plenum ceiling 351 slopes from a maximum height at supply zone 350a to a minimum height at terminal zone 350b.

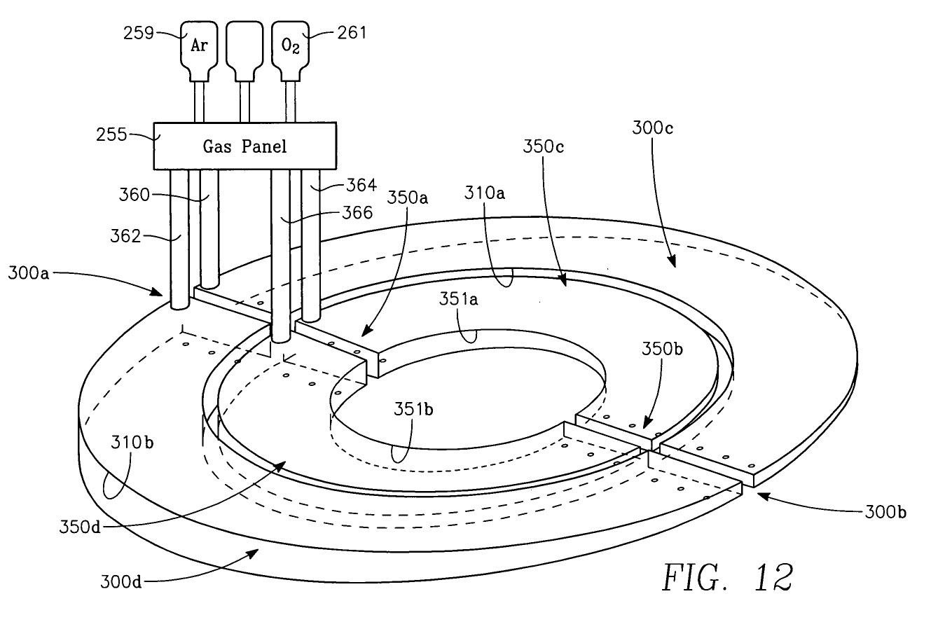

FIG. 12 depicts a variation of the embodiment of FIG. 10, in which two semi-annular plenums 350c, 350d provide an inner gas distribution zone while the semi-annular plenums 300c, 300d provide an outer gas distribution zone. The inner semi-annular plenums 350c, 350d are similar in structure to the outer semi-annular plenums 300c, 300d. Each inner semi-annular plenum 350c, 350d has its own sloping ceiling 351a, 351b. Each semi-annular plenum 300c, 300d, 350c, 350d receives process gas through a respective inlet 360, 362, 364, 366.

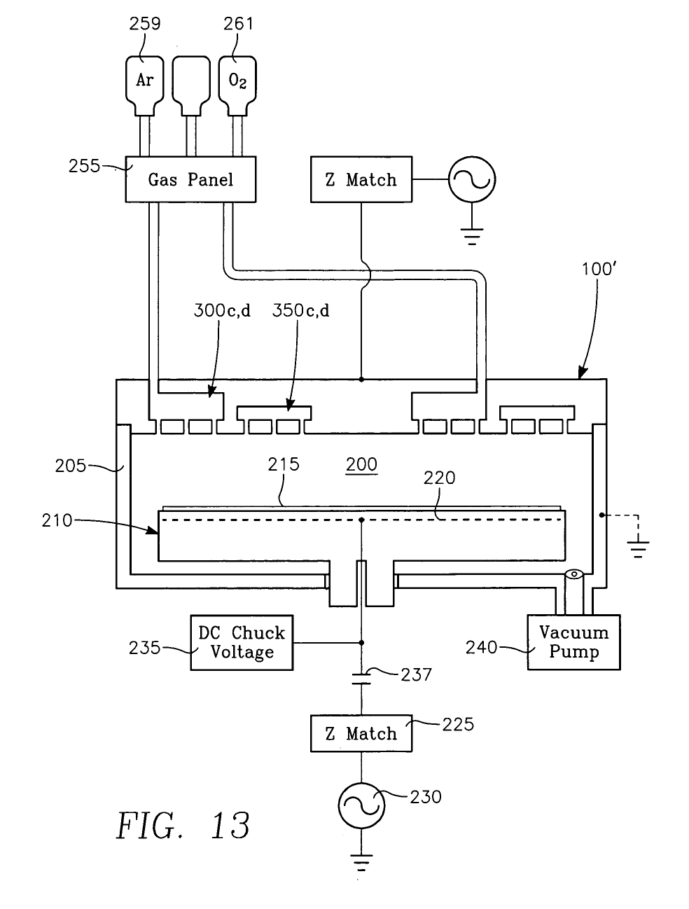

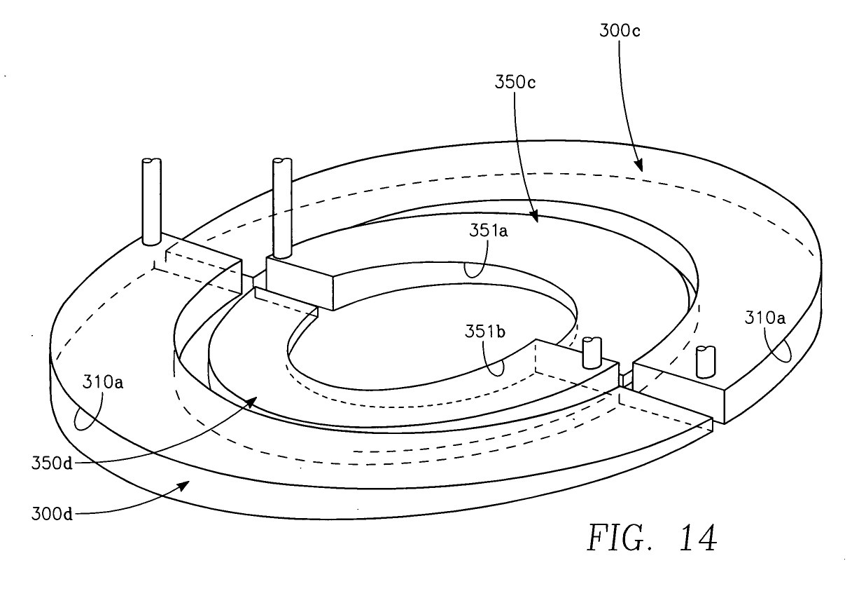

The embodiment of FIG. 12 is depicted as having all gas inlets 360, 362, 364, 366 adjacent one another. The inner and outer plenum ceilings 310a, 310b, 351a, 351b slope in the same azimuthal direction. FIGS. 13 and 14 depict a variation of the embodiment of FIG. 12, in which gas inlets to respective half-plenums are located on opposing ends so as to be displaced azimuthally from one another by 180 degrees. In the embodiment of FIGS. 13 and 14, the ceilings 310a, 310b of the semi-annular plenums 300c, 300d slope in opposite azimuthal directions. Also, the ceilings 351a, 351b of the semi-annular plenums 350c, 350d slope in opposite azimuthal directions.

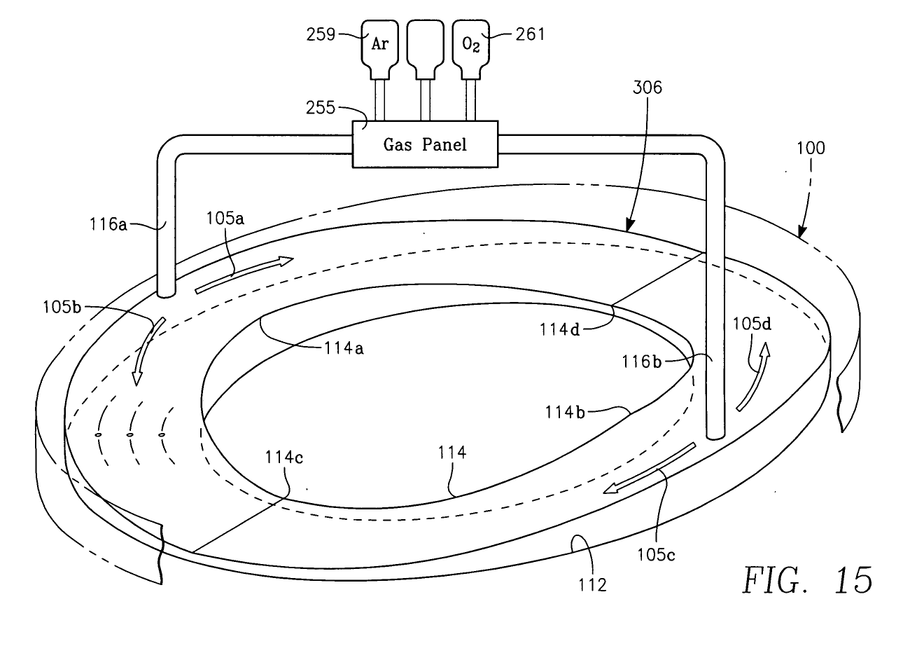

While the foregoing description included embodiments in which a single plenum has a single gas supply or inlet, FIG. 15 depicts an embodiment in which an annular plenum 306 has a pair of gas supply inlets 116a, 116b displaced from one another by 180 degrees of azimuth (circumferential travel around the annular plenum 306). The ceiling 114 slopes along the azimuth direction, having two peaks 114a, 114b near or at the respective gas supply inlets 116a, 116b, and having valleys or nulls 114c, 114d at respective midpoints between the two peaks 114a, 114b. In one embodiment, the peaks 114a, 114b are displaced from one another by 180 degrees of azimuthal travel along the plenum 306. The nulls 114c, 114d are displaced from one another by 180 degrees of azimuthal travel along the plenum 306. The nulls 114c, 114d are displaced from respective ones of the peaks 114a, 114b, by 90 degrees of azimuthal travel. Process gas flow from the inlet 116a is along a clockwise path 105a and a counterclockwise path 105b from the ceiling peak 114a toward the respective ceiling nulls 114c, 114d. Process gas flow from the inlet 116b is along a clockwise path 105c and a counterclockwise path 105d from the ceiling peak 114b toward the respective ceiling nulls 114c, 114d. As shown in FIG. 15, the ceiling 114 has four sloped sections, namely a first section sloping downwardly from the ceiling peak 114a to the ceiling null 114c, a second section sloping downwardly from the ceiling peak 114a to the ceiling null 114d, a third section sloping downwardly from the ceiling peak 114b to the ceiling null 114c and a fourth section sloping downwardly from the ceiling peak 114b to the ceiling null 114d. Slope in each of these sections is sufficient to provide a more uniform distribution of gas flow along the azimuthal length of the plenum 306.

While the foregoing embodiments have been described with respect to a plenum that is internal within a gas distribution plate or ceiling, in other embodiments the plenum may be an external structure feature supported by or suspended from the ceiling or plate.

While the foregoing is directed to embodiments of the invention, other and further embodiments of the invention may be devised without departing from the basic scope thereof, and the scope thereof is determined by the claims that follow.

What is claimed is:

1. A gas distribution plate comprising:
a disk-shaped plate;
a first hollow annular plenum within or supported by said disk-shaped plate, said annular plenum being concentric with an axis of symmetry of said disk-shaped plate, said plenum comprising an annular floor and an annular ceiling facing said annular floor;
plural gas injection holes in said floor;
a gas injection port coupled to said plenum at a supply end of said plenum; and
said annular ceiling having a height above said annular floor, said height being maximum at said supply end of said plenum, said ceiling sloping toward said floor along an azimuthal path of said plenum whereby said height decreases along said azimuthal path.

2. The apparatus of claim 1 wherein said ceiling slopes sufficiently so that said height decreases by a factor of two or more over 360 degrees of travel along said azimuthal path.

3. The apparatus of claim 1 wherein said ceiling slopes sufficiently so that said height decreases by a factor of two or more over 180 degrees of travel along said azimuthal path.

4. The apparatus of claim 1 wherein said slope is sufficient to maintain uniform gas pressure along said azimuthal path of said plenum.

5. The apparatus of claim 1 wherein said azimuthal path makes a 360 degree circuit, said plenum further comprising a barrier blocking said azimuthal path and having one surface facing a beginning of said azimuthal path and an opposite surface defining an end of said azimuthal path, said beginning of said azimuthal path coinciding with said supply end of said plenum.

6. The apparatus of claim 1 wherein said ceiling slopes from a maximum height at said supply end to a minimum height at a terminal location displaced by 180 degrees of travel along said azimuthal path from said supply end.

7. The apparatus of claim 6 wherein said plenum provides two opposing 180 degree azimuthal paths from said supply end to said terminal end.

8. The apparatus of claim 1 wherein said plenum further comprises a barrier blocking said azimuthal path at a location displaced from said supply end of said plenum by 180 degrees of travel along said azimuthal path.

9. The apparatus of claim 8 wherein said ceiling slopes toward said floor beginning at a maximum height at said supply end and ending at a minimum height at said barrier.

10. The apparatus of claim 9 wherein said barrier divides said azimuthal path into two azimuthal 180 degree paths, said ceiling sloping equally along both of said 180 degree paths.

11. The apparatus of claim 7 wherein said gas supply port feeds both of said two opposing azimuthal paths.

12. The apparatus of claim 8 further comprising a divider separating said supply end into a pair of supply ends and said gas supply port comprises first and second ports coupled separately to said pair of supply ends.

13. The apparatus of claim 1 further comprising a second hollow annular plenum concentric with and surrounding said first hollow annular plenum, said second annular plenum comprising a second annular floor, a second annular ceiling facing said second annular floor and plural gas injection holes in said floor and a second gas injection port coupled to said second plenum at a supply end of said second plenum.

14. The apparatus of claim 13 wherein:
said second annular ceiling has a height above said second annular floor, said height being maximum at said supply end of said second plenum, said second ceiling sloping toward said second floor along an azimuthal path of said second plenum whereby said height decreases along said azimuthal path of said second plenum.

15. The apparatus of claim 13 wherein said second ceiling slopes sufficiently so that said height decreases by a factor of two or more over 360 degrees of travel along said azimuthal path of said second plenum.

16. The apparatus of claim 13 wherein said second ceiling slopes sufficiently so that said height decreases by a factor of two or more over 180 degrees of travel along said azimuthal path of said second plenum.

17. The apparatus of claim 13 wherein said slope of said second ceiling is sufficient to maintain uniform gas pressure along said azimuthal path of said second plenum.

18. The apparatus of claim 13 wherein said first second ceilings slope in the same azimuthal direction.

19. The apparatus of claim 13 wherein said first and second ceiling slope in opposing azimuthal directions.

20. A gas distribution plate comprising:
a disk-shaped plate;
a hollow annular plenum within or supported by said disk-shaped plate, said annular plenum being concentric with an axis of symmetry of said disk-shaped plate, said plenum comprising an annular floor and an annular ceiling facing said annular floor;
plural gas injection holes in said floor;
plural gas injection ports coupled to said plenum, said injection ports being spaced from one another along an azimuthal path of said plenum; and
said annular ceiling having respective peaks of maximum heights above said annular floor at respective ones of said injection ports and having nulls of minimum heights above said annular floor at respective midpoints along said azimuthal path between respective pairs of said injection ports, said ceiling having respective slopes from each peak toward respective ones of said nulls.

21. A plasma reactor chamber comprising:
a vacuum chamber;
a support placed inside the vacuum chamber to hold a substrate;
a gas distribution plate configured to allow an injection of a gas into the chamber, wherein the gas distribution plate further comprises
a first hollow annular plenum within or supported by said plate, said annular plenum being concentric with an axis of symmetry of said plate, said plenum comprising an annular floor and an annular ceiling facing said annular floor;
plural gas injection holes in said floor;
a gas injection port coupled to said plenum at a supply end of said plenum; and
said annular ceiling having a height above said annular floor, said height being maximum at said supply end of said plenum, said ceiling sloping toward said floor along an azimuthal path of said plenum whereby said height decreases along said azimuthal path.

22. A plasma reactor chamber comprising:
a vacuum chamber;
a support placed inside the vacuum chamber to hold a substrate;
a gas distribution plate configured to allow an injection of a gas into the chamber, wherein the gas distribution plate further comprises
a disk-shaped plate;
a hollow annular plenum within or supported by said disk-shaped plate, said annular plenum being concentric with an axis of symmetry of said disk-shaped plate, said plenum comprising an annular floor and an annular ceiling facing said annular floor;
plural gas injection holes in said floor;
plural gas injection ports coupled to said plenum, said injection ports being spaced from one another along an azimuthal path of said plenum; and
said annular ceiling having respective peaks of maximum heights above said annular floor at respective ones of said injection ports and having nulls of minimum heights above said annular floor at respective midpoints along said azimuthal path between respective pairs of said injection ports, said ceiling having respective slopes from each peak toward respective ones of said nulls.
